(19) United States
(12) Patent Application Publication
(10) Pub. No.: US 2026/0358372 A1
(43) Pub. Date: Nov. 12, 2026

(54) PROBE PIN HAVING PRECISELY DEFINED SELECTIVE CONDUCTIVE LAYER STRUCTURE AND MANUFACTURING METHOD THEREOF

(71) Applicant: WithMEMS Co., Ltd., Hwaseong-si (KR)

(72) Inventors: Hwang-sub KOO, Hwaseong-si (KR); Jong-Uk BU, Hwaseong-si (KR); Ho Sub BANG, Hwaseong-si (KR); Jong Han LEE, Hwaseong-si (KR); Sanghyeop LEE, Hwaseong-si (KR); Jaewoo CHA, Hwaseong-si (KR); Kwang Young PARK, Hwaseong-si (KR); Min Hwan YOON, Hwaseong-si (KR)

(73) Assignee: WithMEMS Co., Ltd., Hwaseong-si (KR)

(21) Appl. No.: 19/353,723

(22) Filed: Oct. 9, 2025

(30) Foreign Application Priority Data
May 9, 2025 (KR) 10-2025-0060315

(51) Int. Cl. G01R 1/067; G01R 3/00

(52) U.S. Cl. CPC G01R 1/06761; G01R 1/06727; G01R 3/00

(57) ABSTRACT

Proposed are a probe pin having a precisely defined selective conductive layer structure and a manufacturing method thereof. The probe pin having the precisely defined selective conductive layer structure includes a pin body portion including a bonding portion bonded to a pad of a card substrate via solder, an elastic portion extending from the bonding portion, and a pin header portion extending from the elastic portion, and a pin tip portion formed on a second side of the pin header portion, wherein the lowermost surface of the pin body portion is formed as a conductive layer having a higher solder affinity than the pin tip portion.

### CROSS REFERENCE TO RELATED APPLICATION

The present application claims priority to Korean Patent Application No. 10-2025-0060315, filed on May 9, 2025, the entire contents of which are incorporated herein by reference in their entirety.

### BACKGROUND OF THE INVENTION

### Field of the Invention

The present disclosure relates generally to a probe pin having a precisely defined selective conductive layer structure and a manufacturing method thereof. More particularly, the present disclosure relates to a probe pin having a precisely defined selective conductive layer structure for simultaneously improving performance related to electrical characteristics and service life, and a manufacturing method thereof.

### Description of the Related Art

Probe cards are used to test the electrical characteristics of integrated circuit (IC) devices on a semiconductor wafer. A probe card generally consists of a card substrate formed of a multilayer circuit board, and probe pins bonded to pads on the surface of the card substrate.

The probe card may further include, in addition to the probe pins that make contact with IC devices on a semiconductor wafer to receive signals and the card substrate that receives signals from the probe pins and transmits the signals to a tester, a space transformer that transmits signals between the probe pins and the card substrate.

That is, the probe pins may be bonded to the space transformer, and the entire configuration to which the probe pins are bonded, including the space transformer, may be collectively referred to as pads of the card substrate.

The bonding between a pad of the card substrate and a probe pins is carried out via solder. In order to improve the bonding strength by promoting the spreading of the solder, a conductive layer formed with a non-oxidizing, clean-surface material (e.g., gold (Au)) is plated on the surface of the probe pin. At this time, when a conductive layer of a material such as gold (Au) is plated on the surface of the probe pin, solder (soldering alloy, e.g., SnAgCu) spreads well across the surface of the conductive layer due to its excellent wettability, thereby enhancing the bonding strength between the pad of the card substrate and the probe pin.

Here, the term “conductive layer” used to refer to a coating layer plated on the surface of the probe pin is intended not only to denote that the plated material improves the bonding strength between a pad of the probe card and the probe pin via solder, but also to encompass the requirement of enhancing performance related to the electrical characteristics of a signal transmission path formed between a pin tip portion of the probe pin and the probe card.

More specifically, in describing a probe pin according to the related art, the probe pin includes a bonding portion that is bonded to a pad of a card substrate, a support portion that extends from one side of the bonding portion, an elastic portion (beam portion) that extends from the support portion in a direction parallel to the bonding portion, and a pin tip portion that extends from the elastic portion (beam portion). The pin tip portion is the part that makes contact with a pad of an IC device to be inspected and is formed with a sharp end. To allow the pin tip portion to make contact with the pad of the IC device with a predetermined pressure, the elastic portion (beam portion) is configured to be elastically deformable, for example, by including a hollow portion.

Since electrical signals are transmitted between the card substrate and the IC device through the probe pin, a body of the probe pin is formed with an electrically conductive metal or alloy, for example, a nickel-cobalt (Ni-Co) alloy. The aforementioned conductive layer is plated over the entire surface of the body of the probe pin. This conductive layer is provided not only to prevent the body of the probe pin from being oxidized or corroded, but also to allocate solder affinity. That is, when soldering the probe pin to the pad of the card substrate, molten solder needs to spread uniformly between the bottom surface of the bonding portion and the pad to ensure the bonding strength of the probe pin, which requires a solder-affinity layer such as the conductive layer on the surface of the probe pin.

Meanwhile, as IC devices miniaturize, the probe pins provided on the probe card become denser, making the reliability of a soldering process for bonding the probe pins to the pads on the card substrate increasingly critical. The soldering process is in general achieved in the following manner. First, an appropriate amount of solder is placed on a pad of the card substrate. Then, a probe pin, previously manufactured in a separate process, is transferred using a probe pin holder so that the bottom surface of the bonding portion of the probe pin is positioned on the solder. Subsequently, energy from a laser or the like melts the solder. At this time, the bonding strength of the probe pin can vary significantly depending on the precision with which the soldering process is controlled, such as the amount of solder and the amount of energy applied to the solder.

The probe pin is bonded to the pad of the card substrate using solder as an intermediary. A precisely controlled soldering process allows the solder to spread along the interface between the pad and the bonding portion as well as over the pad surface and up to a predetermined height of the bonding portion, thereby ensuring that the probe pin is firmly secured to the pad. On the other hand, insufficient energy applied to the solder or non-precise control over the process prevents the solder from properly flowing up along the side of the bonding portion, resulting in a very low solder height. Excessive energy applied to the solder leads to excessive solder flowing up along the side of the bonding portion over the conductive layer with strong solder affinity, while only a small amount of solder remains on the pad surface. In both cases, a weak bond is created between the probe pin and the pad, so when a lateral force is applied to the probe pin, it may be detached even with relatively little force.

To address this issue, increasing the amount of solder may be considered. However, an increased solder amount may cause short-circuiting between adjacent probe pins and also lead to a higher height of the solder flowing up along the bonding portion, potentially contaminating the probe pin holder.

Moreover, even with precisely controlled energy applied to the solder, it is difficult to ensure that the same level of energy is applied to different areas of the card substrate in the actual manufacturing process. Additionally, the solder amount used for each probe pin-pad pair may vary slightly, making it challenging to achieve uniform bonding strength for all probe pins within a single probe card.

Furthermore, since the aforementioned conductive layer is plated over the entire probe pin, including the pin tip portion, repeated contact of the pin tip portion with an inspection target object may cause the conductive layer to peel off from the pin tip portion. In addition to peeling off of the conductive layer, during sliding motion of the pin tip portion over the pad to establish electrical contact, debris including fragments of the pad material (e.g., Cu) may accumulate around the pin tip portion. This necessitates an increase in the number of cleaning cycles of the pin tip portion to remove such debris during the semiconductor testing process, which ultimately reduces the pin tip portion’s lifespan and deteriorates its contact performance.

Additionally, during a laser bonding process in which the probe pin is bonded to the pad of the card substrate via solder, the solder may spread away from the intended bonding area and climb up adjacent surfaces or nearby components, which is a phenomenon known as solder wicking. The occurrence of such solder wicking may lead to a reduction in the bonding strength between the probe pin and the pad of the card substrate.

Thus, a solution capable of addressing all the problems described above is required.

The foregoing is intended merely to aid in the understanding of the background of the present disclosure, and is not intended to mean that the present disclosure falls within the purview of the related art that is already known to those skilled in the art.

### Documents of Related Art

(Patent document 1) Korean Patent No. 10-1839366 (2018.03.12.)

### SUMMARY OF THE INVENTION

Accordingly, the present disclosure has been made keeping in mind the above problems occurring in the related art, and one objective of the present disclosure is to provide a probe pin having a precisely defined selective conductive layer structure and a manufacturing method thereof, in which the probe pin is manufactured based on a conductive layer generation method employing precisely controlled selective lamination and pattern plating, thereby enhancing performance related to electrical characteristics, enhancing performance capable of preventing contamination and damage to the pin tip, and reliably improving solder bonding strength with a pad of a card substrate.

The objectives of the present disclosure is not limited to those mentioned above, and other objectives not mentioned will be clearly understood by those skilled in the art from the following description.

In order to achieve the above objective, according to a first aspect of the present disclosure, there is provided a probe pin having a precisely defined selective conductive layer structure, the probe pin including: a pin body portion including a bonding portion bonded to a pad of a card substrate via solder, an elastic portion extending from the bonding portion, and a pin header portion extending from the elastic portion; and a pin tip portion formed on a second side of the pin header portion, wherein a lowermost surface of the pin body portion may be formed as a conductive layer having a higher solder affinity than the pin tip portion.

The probe pin may further include: a pattern plating portion in which a conductive layer is pattern-plated only on a specific area free of the conductive layer on a surface of the pin body portion.

The bonding portion may include: a soldering area provided in at least one part of the pin body portion and in which the solder is applied and melted; a solder wicking prevention area in which the conductive layer is not pattern-plated; and a boundary area formed at a boundary between the soldering area and the solder wicking prevention area.

The conductive layer may include at least one selected from copper (Cu), gold (Au), silver (Ag), and alloys thereof.

The pin tip portion may include: a pad contact area making contact with a pad to be inspected; and a header connection area connected to the pin header portion, wherein a part of the header connection area may be pattern-plated with the conductive layer.

An area to be pattern-plated may be precisely selectively defined through a photolithography process.

The solder wicking prevention area may be excluded from pattern plating by the photolithography process.

The solder wicking prevention area may be surrounded by the conductive layer to form an enclosed structure.

A size of the solder wicking prevention area may be determined based on a diffusion distance of the solder applied to the soldering area during bonding at the soldering area.

The conductive layer may be further formed on an inner layer of the pin body portion either as a single structure or as a multi-layer structure.

Laminated contact surfaces of the pin header portion and the header connection area may include one or more interlocking engagement structures.

According to a second aspect of the present disclosure, there is provided a manufacturing method of a probe pin including a pin body portion including a bonding portion bonded to a pad of a card substrate via solder, an elastic portion extending from the bonding portion, and a pin header portion extending from the elastic portion, and a pin tip portion formed on a second side of the pin header portion, the manufacturing method including: forming a conductive layer having a higher solder affinity than the pin tip portion on a lowermost surface of the pin body portion.

The manufacturing method may further include: pattern-plating the conductive layer only on a specific area free of the conductive layer on a surface of the pin body portion.

The manufacturing method may further include: dividing the bonding portion into a soldering area in which the solder is applied and melted, a solder wicking prevention area in which the conductive layer is not pattern-plated, and a boundary area formed at a boundary between the soldering area and the solder wicking prevention area.

The manufacturing method may further include: dividing the pin tip portion into a pad contact area making contact with a pad to be inspected and a header connection area connected to the pin header portion, and pattern-plating a part of the header connection area with the conductive layer.

According to the present disclosure having the above-configuration, the probe pin is manufactured based on a conductive layer generation method employing precisely controlled selective lamination and pattern plating. Thus, it is possible to enhance performance related to electrical characteristics, enhance performance capable of preventing contamination and damage to the pin tip portion, and reliably improve solder bonding strength with the pad of the card substrate.

The effects of the present disclosure is not limited to those mentioned above, and other effects not mentioned will be clearly understood by those skilled in the art from the following description.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a view illustrating a probe pin according to an embodiment of the present disclosure;

FIG. 2 is a view illustrating an example of a manufacturing process of a probe pin illustrated in FIG. 1;

FIG. 3 is a view illustrating a header connection area added to the state in i) of FIG. 2;

FIGS. 4A, 4B, and 4C are views illustrating an example of an enlarged cross-section of portion B in i) of FIG. 2;

FIGS. 5A, 5B, and 5C are views illustrating another example of an enlarged cross-section of portion B in i) of FIG. 2;

FIGS. 6A and 6B are cross-sectional views of i) of FIG. 2 from a different perspective, illustrating a comparison with the related art;

FIG. 7 is a view illustrating in more detail each part of the probe pin in FIG. 1; and

FIG. 8 is a view illustrating another example of a manufacturing process of a probe pin illustrated in FIG. 1.

### DETAILED DESCRIPTION OF THE INVENTION

Reference will now be made in greater detail to exemplary embodiments of the present disclosure, examples of which are illustrated in the accompanying drawings. The scope of the claims, however, should not be construed as limited to the exemplary embodiments set forth herein. Like reference numerals in the drawings refer to like elements throughout.

Various modifications may be made to the embodiments described hereinbelow. The following embodiments are not construed as limited to the disclosure and should be understood to include all changes, equivalents, and substitutions within the idea and the technical scope of the disclosure.

It will be understood that, although the terms first, second, etc. may be used herein to describe various elements, these elements should not be limited by these terms. These terms are only used to distinguish one element, from another element. For instance, a first element discussed below could be termed a second element without departing from the teachings of the present disclosure. Similarly, the second element could also be termed the first element.

The terminology used herein is for the purpose of describing particular embodiments only and is not intended to be limiting. As used herein, the singular forms are intended to include the plural forms as well, unless the context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. The terms “comprise”, “include”, “have”, etc. when used in this specification, specify the presence of stated features, integers, steps, operations, elements, components, and/or combinations thereof but do not preclude the presence or addition of one or more other features, integers, steps, operations, elements, components, and/or combinations thereof.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Further, like reference numerals are used to identify like elements throughout different drawings, and a repeated description related thereto will be omitted. When it is determined that detailed description of the known art might obscure the gist of the present disclosure in describing the embodiments, the detailed description will be omitted here.

A probe pin having a precisely defined selective conductive layer structure and a manufacturing method thereof according to the present disclosure are characterized in that the probe pin is manufactured based on a conductive layer generation method employing precisely controlled selective lamination and pattern plating, thereby enhancing performance related to electrical characteristics, enhancing performance capable of preventing contamination and damage to a pin tip portion, and reliably improving solder bonding strength with a pad of a card substrate.

Hereinafter, preferred embodiments of the present disclosure will be described in detail with reference to the accompanying drawings.

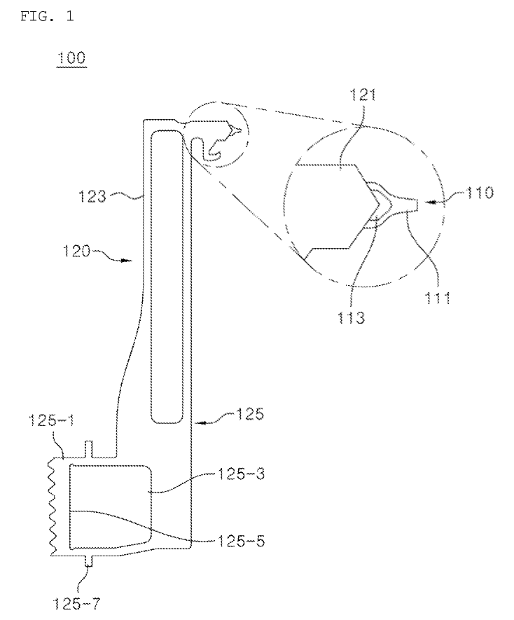

FIG. 1 is a view illustrating a probe pin according to an embodiment of the present disclosure.

As illustrated in FIG. 1, a probe pin 100 having a precisely defined selective conductive layer structure includes: a pin body portion 120 including a bonding portion 125 bonded to a pad of a card substrate via solder, an elastic portion 123 extending from the bonding portion 125, and a pin header portion 121 extending from the elastic portion 123; and a pin tip portion 110 formed on a second side of the pin header portion 121, wherein the lowermost surface of the pin body portion 120 is formed as a conductive layer C1 having a higher solder affinity than the pin tip portion 110.

Here, forming the lowermost surface of the pin body 120 as the conductive layer C1 means that the conductive layer C1 is laminated on one surface of the pin body portion 120 excluding the pin tip portion 110.

Additionally, the probe pin 100 of the present disclosure may further include a pattern plating portion (referred to as the area where C2 is plated) in which a conductive layer C2 is pattern-plated only on a specific area free of the conductive layer C1 on the surface of the pin body portion 120.

That is, by forming the conductive layers C1 and C2 on the pin body portion 120 excluding the pin tip portion 110, peeling off of the conductive layers C1 and C2 caused by repeated contact of the pin tip portion 110 with a pad to be inspected can be prevented. Furthermore, dividing the conductive layers C1 and C2 on the pin body portion 120 into the conductive layer C1 formed by lamination and the conductive layer C2 formed by pattern plating makes it possible to more easily enhance electrical conduction efficiency and contact characteristics.

To further elaborate on the foregoing, forming the conductive layer C1 of the pin body portion 120 with a thickness of about 1 to 10 μm (preferably 2 to 5 μm) reduces electrical resistance by increasing the cross-sectional area for conduction, thereby improving electrical conduction efficiency. Such thickness control of the conductive layer C1 is preferably achieved through a lamination method.

Additionally, the conductive layer C2 of the pin body portion 120 is the part that requires consideration of solder-mediated contact characteristics, wear resistance, and electrical conductivity. For this purpose, it is preferable to apply a pattern plating method. This method is suitable for forming the conductive layer C2 of the pin body portion 120 with a thickness of about 0.1 to 1.0 μm (preferably 0.2 to 0.5 μm) and is also cost-effective and process-efficient when applied to most surfaces of the pin body portion 120.

This pattern plating portion (referred to as the area where C2 is plated) denotes a part of the probe pin 100 where the conductive layer C2 is pattern-plated. For example, it may include a part where the conductive layer C2 is pattern-plated on a part of a header connection area 113 of the pin tip portion 110 to be described later is pattern-plated, and a part where the conductive layer C2 is pattern-plated on the surface of the pin body portion 120. At this time, a predetermined area (e.g., a solder wicking prevention area 125-3 to be described later) of the surface of the pin body portion 120 may be excluded from pattern plating.

For example, the conductive layer C1 having a higher solder affinity than the pin tip portion 110 may be formed on the lowermost surface of the pin body portion 120, and the pattern plating portion where the conductive layer C2 is pattern-plated may be provided only on a specific area free of the conductive layer C1 on the surface of the pin body portion 120. The conductive layer C2 may be plated on the surface of the pin body portion 120 including a side surface, and may not be plated on a pad contact area of the pin tip portion 110 that makes contact with the pad to be inspected.

The bonding portion 125 may include a support portion (not illustrated) provided on one side of the bonding portion 125 to support the elastic portion 123. As illustrated in FIG. 1, when the probe pin 110 of the present disclosure is configured as a blade type, the bonding portion 125 may be formed with a wide and flat surface, thereby ensuring characteristics such as suitability for solder bonding, wettability, fixation, and sufficient bonding area.

The pin tip portion 110 may be divided into a pad contact area 111 making contact with a pad of an integrated circuit device to be inspected (hereinafter referred to as a “pad to be inspected”), and the header connection area 113 connected to the pin header portion 121.

Additionally, the pad contact area 111 of the pin tip portion 110 may have an edge or micro-tip structure to reduce contact resistance and ensure precise contact with the pad to be inspected. Through this edge or micro-tip structure, a face contact configuration can be implemented, which minimizes damage to the pad to be inspected while maintaining stable electrical contact characteristics.

The pin tip portion 110 is formed with a high-hardness metal. When the pin tip portion 110 is formed by laminating at least one metal selected from rhodium (Rh), palladium (Pd), ruthenium (Ru), and alloys thereof, preferably Rh (rhodium), on the high-hardness metal, it is preferable that the pin tip portion 110 has a minimal size sufficient to make contact with the pad to be inspected and transmit signals to the pin body portion 120. To support this, a part of the pin tip portion 110 connected to the pin header portion 121 may have a structure inserted into the pin header portion 121.

A part of the pin header portion 121 may overlap a part of the pin tip portion 110. By pattern-plating this overlapping portion with the conductive layer C2, the electrical conductivity of the pin tip portion 110 in contact with the pad to be inspected can be efficiently maintained. This enhances the electrical flow efficiency along the electrical flow path from the pin body portion 120 to the pin tip portion 110.

This refers to pattern plating of a part of the header connection area 113 of the pin tip portion 110 with the conductive layer C2, as described above.

The conductive layer C2 may be at least one selected from copper (Cu), gold (Au), silver (Ag), and alloys thereof. Additionally, the conductive layer C1 to be laminated may also be one or more selected from copper (Cu), gold (Au), silver (Ag), and alloys thereof.

The pin tip portion 110 of the present disclosure does not have the conductive layer C1 or C2 either laminated or plated. This is to prevent the conductive layer C1 or C2 from peeling off or being damaged due to repeated contact with the pad to be inspected, which otherwise generates debris around the pin tip portion 110. By avoiding this, the number of cleaning cycles of the pin tip portion 110 to remove such debris during the semiconductor testing process can be reduced, thereby preventing a decrease in the lifespan of the pin tip portion 110 and a deterioration in the contact performance of the pin tip portion 110.

Accordingly, the pin tip portion 110 of the present disclosure may be either laminated or plated with a metal such as rhodium (Rh) to enhance its contact function with the pad to be inspected, and may be configured with a lubricating or protective layer while maintaining electrical conductivity.

However, the electrical conductivity of rhodium (Rh) is 2.00 × 10⁷ S/m, which is lower than that of gold (Au) (4.10 × 10⁷ S/m). To compensate for this limitation, the pin tip portion 110 of the present disclosure is divided into the pad contact area 111 formed with a metal such as rhodium (Rh) and the header connection area 113 connected to the pin header portion 121, and then a part of the header connection area 113 is pattern-plated with a conductive layer (e.g., gold (Au), C2).

In other words, even with repeated contact with the pad to be inspected, the lifespan of the pin tip portion 110 can be extended via the pad contact area 111 formed with a metal such as rhodium (Rh). By pattern-plating the header connection area 113 distinguished from the pad contact area 111 with the conductive layer (e.g., gold (Au), C2), the electrical path through the rhodium-based pad contact area 111 can be effectively shortened, and the electrical conductivity can be further enhanced via the conductive layer (e.g., gold (Au), C2) of the header connection area 113.

Since the pin body portion 120, including a part of the aforementioned header connection area 113, has the conductive layer (e.g., gold (Au), C1 and C2) with high solder affinity exposed on an outer surface thereof, it can reliably deliver signals transmitted through the pad contact area 111 of the pin tip portion 110 and the header connection area 113 to the pad of the card substrate bonded to the bonding portion 125 of the pin body portion 120 while maintaining the electrical characteristics of the signals.

The bonding portion 125 of the probe pin 100 may include a soldering area 125-1 provided in at least one part of the pin body portion 120 and in which the solder is applied and melted, a solder wicking prevention area 125-3 in which the conductive layer C2 is not pattern-plated, and a boundary area formed at the boundary between the soldering area 125-1 and the solder wicking prevention area 125-3.

The areas where pattern plating is to be applied, i.e., a part of the header connection area 113 of the pin tip portion 110 and the pin body portion 120, may be precisely selected through a photolithography process and pattern-plated.

Additionally, the solder wicking prevention area 125-3 may be excluded from pattern plating by the photolithography process, and may be surrounded by the conductive layer C2 to form an enclosed structure. That is, since the solder wicking prevention area 125-3 is not pattern-plated with the conductive layer C2, the laminated appearance (e.g., Ni alloy) of the bonding portion 125 is exposed. During a bonding process in which the soldering area 125-1 is bonded to the pad of the card substrate via solder, the solder wicking prevention area 125-3 serves to prevent a solder wicking phenomenon in which molten solder spreads away from the soldering area 125-1 and climbs up an unintended part.

The size of the solder wicking prevention area 125-3 may be determined based on the diffusion distance of the solder applied to the soldering area 125-1 during bonding at the soldering area 125-1.

Additionally, a bridge 125-7 that serves as a path for electroplating may be provided on at least one side of the bonding portion 125.

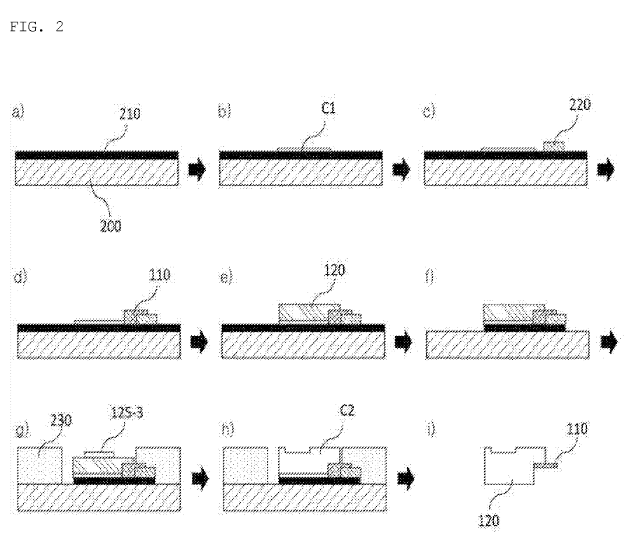

FIG. 2 is a view illustrating an example of a manufacturing process of a probe pin illustrated in FIG. 1.

As illustrated in FIG. 2, a manufacturing process of a probe pin 100 according to the present disclosure first involves forming a seed layer 210 on a wafer base 200 (e.g., Si, glass, ceramic) (a).

For example, the seed layer 210 in step (a) is formed by depositing thin films of titanium (Ti) and copper (Cu) on the wafer base 200 (e.g., Si, glass, ceramic). This seed layer 210 serves as the foundation for the plating process, providing a basis on which subsequent metal thin films can uniformly grow on the wafer.

Subsequently, the lowermost surface of the pin body portion 120 is laminated with a conductive layer C1 (e.g., gold (Au)) (b), and a support structure 220 serving as a support for a pin tip portion 110 of the probe pin 100 is formed (c).

At this time, the conductive layer C1 (e.g., gold (Au)) may be formed with a metal having a higher solder affinity than the pin tip portion 110. This conductive layer C1 (e.g., gold (Au)) may be formed through a photolithography process in areas excluding a solder wicking prevention area 125-3 to be described later.

Additionally, it is preferable that the support structure 220 is formed with a metal that is selectively wet-etchable. For example, it is preferably formed with copper.

Based on the laminated state of step (c), the pin tip portion 110 is formed (d). It is preferable that the pin tip portion 110 is formed with a metal having a higher hardness than the conductive layer C1 and the pin body portion 120 to be described later. For example, it is preferably formed with rhodium (Rh).

After laminating the pin tip portion 110 in step (d), the pin body portion 120 is formed (e). The pin body portion 120 may be formed with nickel (Ni) or a nickel alloy (e.g., Ni-Co alloy). The pin body portion 120 contributes to maintaining the main structural shape of the probe pin 100 (e).

After step (e), a process of etching unnecessary portions of the seed layer 210 used in the previous step is carried out (f). Through this etching process, only a required portion, i.e., a selected area, is left.

After step (f), a process of defining a specific area to be pattern-plated on the probe pin 100 is carried out (g). For example, the specific area to be pattern-plated on the probe pin 100 may be selected through a photolithography process.

Subsequently, a conductive layer C2 (e.g., gold (Au)) is patterned-plated onto the precisely selected area defined in step (g) (h). For example, the precisely selected area in step (g) may correspond to an area excluding the pin tip portion 110 and the solder wicking prevention area 125-3.

Thereafter, unnecessary portions including the residual seed layer 210 are etched to extract the probe pin (i).

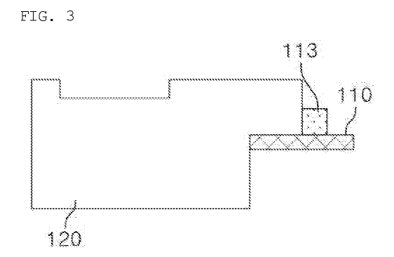

FIG. 3 is a view illustrating a header connection area added to the state in i) of FIG. 2.

As illustrated in FIG. 3, the pin tip portion 110 further includes a header connection area 113 to improve electrical conductivity between the pin tip portion 110 that makes contact with a pad to be inspected and a pin header portion 121.

For example, when the pin header portion 121 is pattern-plated with a conductive layer C2 (e.g., gold (Au)) and the pin tip portion 110 making contact with the pad to be inspected is formed with rhodium (Rh), the electrical conductivity at the boundary between the pin tip portion 110 and the pin header portion 121 may be low or unstable. To compensate for this limitation, a header connection area 113 may be placed at the boundary along the signal transmission path between the pin tip portion 110 and the pin header portion 121. At this time, it is preferable that the header connection area 113 is pattern-plated with a metal or alloy such as the conductive layer C2 (e.g., gold (Au)).

The manufacturing process for providing the header connection area 113 may be carried out by setting precisely defined pattern plating for the pin header portion 121 and the header connection area 113 of the pin tip portion 110 via a photolithography process during pattern plating of the pin body portion 120, and then performing pattern plating based on this setting.

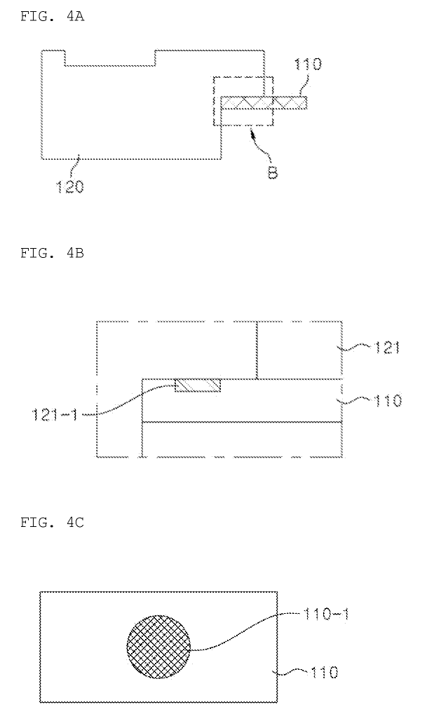

FIGS. 4A, 4B, and 4C are views illustrating an example of an enlarged cross-section of portion B in i) of FIG. 2.

As illustrated in FIG. 4A, a connection portion B between the pin header portion 121 and the pin tip portion 110 may include a shape in which a part of the pin header portion 121 overlaps a part of the pin tip portion 110.

FIGS. 4B and 4C are enlarged views of portion B, in which the contact surfaces of the pin header portion 121 and the pin tip portion 110 may include an interlocking engagement structure.

Here, the interlocking engagement structure may, for example, include a coupling groove 110-1 provided on an upper surface of the pin tip portion 110 at the contact surface of the pin tip portion 110 with the pin header portion 121, and a coupling protrusion 121-1 formed corresponding to the coupling groove 110-1 by laminating the pin header portion 121 to fill the coupling groove 110-1. Ultimately, the interlocking engagement between the coupling groove 110-1 and the coupling protrusion 121-1 can increase the force for keeping the pin tip portion 110 fixed in place.

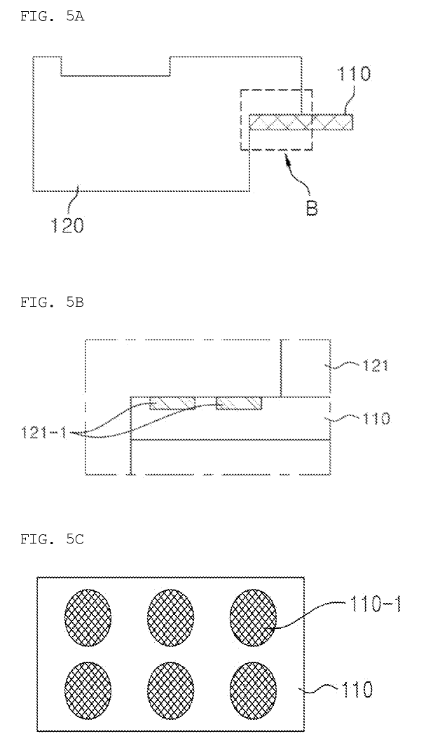

FIGS. 5A, 5B, and 5C are views illustrating another example of an enlarged cross-section of portion B in i) of FIG. 2.

FIGS. 5B and 5C are enlarged views of portion B, in which the contact surfaces of the pin header portion 121 and the pin tip portion 110 may include one or more interlocking engagement structures.

Here, the interlocking engagement structures may, for example, include a plurality of coupling grooves 110-1 provided on an upper surface of the pin tip portion 110 at the contact surface of the pin tip portion 110 with the pin header portion 121, and a plurality of coupling protrusions 121-1 formed corresponding to the plurality of coupling grooves 110-1 by laminating the pin header portion 121 to fill the plurality of coupling grooves 110-1. Ultimately, the interlocking engagement between the plurality of coupling grooves 110-1 and the plurality of coupling protrusions 121-1 can increase the force for keeping the pin tip portion 110 fixed in place.

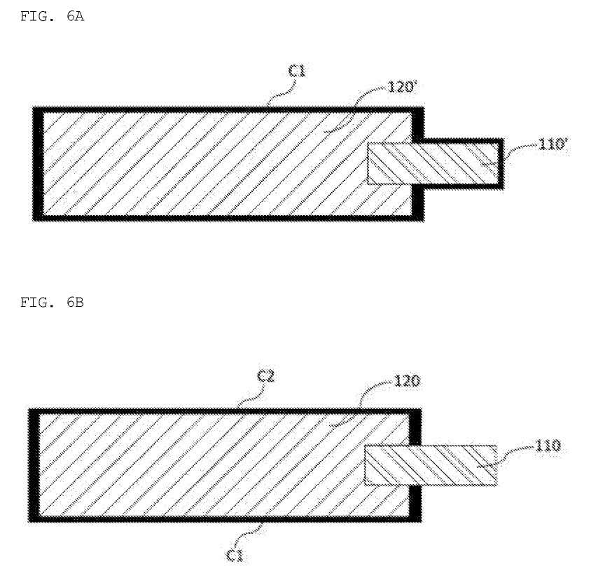

FIGS. 6A and 6B are cross-sectional views of i) of FIG. 2 from a different perspective, illustrating a comparison with the related art.

FIG. 6A depicts a probe pin 100' according to the related art, in which a conductive layer is plated even onto a pin tip portion 110'. This structure is achieved by dipping the probe pin 100' including the pin tip portion 110' and a pin body portion 120' so that the conductive layer is plated continuously onto the pin tip portion 100'.

FIG. 6B depicts the probe pin 100 according to the present disclosure, which is manufactured based on a conductive layer generation method employing precisely controlled selective lamination and pattern plating. This enables selective pattern plating that excludes the pin tip portion 110, while yet reliably improving performance related to electrical characteristics and solder bonding strength with respect to the pad of the card substrate.

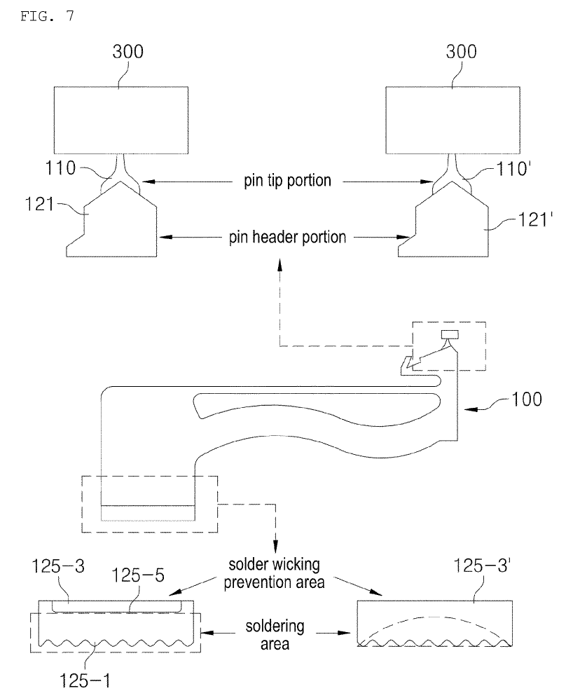

FIG. 7 is a view illustrating in more detail each part of the probe pin in FIG. 1.

As illustrated in FIG. 7, the pin tip portion 110' of the probe pin 100' according to the related art is plated with a conductive layer C2. However, repeated contact of the pin tip portion 110' with the pad causes peeling off of the conductive layer, leading to a deterioration in the performance of the pin tip portion 110'.

On the other hand, since the pin tip portion 110 of the probe pin 100 according to the present disclosure is not plated with the conductive layer C2, peeling off of the conductive layer caused by repeated contact of the pin tip portion 110 with the pad can be prevented. Additionally, the pin tip portion 110 is divided into the pad contact area 111 and the header connection area 113, with the pad contact area 111 formed with a metal such as rhodium (Rh), and a part of the header connection area 113 selectively plated with the conductive layer C2. This configuration maintains the support structure of the pad contact area 111 that makes contact with a pad 300 to be inspected, while minimizing the electric conduction path to the pad contact area 111, thereby improving both structural stability and electrical performance efficiency.

When a bonding portion 125' of the probe pin 100' according to the related art is bonded to the pad of the card substrate via solder, it can be seen, as illustrated in FIG. 7 that the solder spreads non-uniformly. This uneven solder distribution causes solder wicking, which reduces bonding strength or potentially damages nearby components.

On the other hand, when the bonding portion 125 of the probe pin 100 according to the present disclosure is bonded to the pad of the card substrate via solder, as illustrated in FIG. 7, the solder is induced to spread uniformly with respect to the solder boundary area. This structure effectively prevents the occurrence of solder wicking.

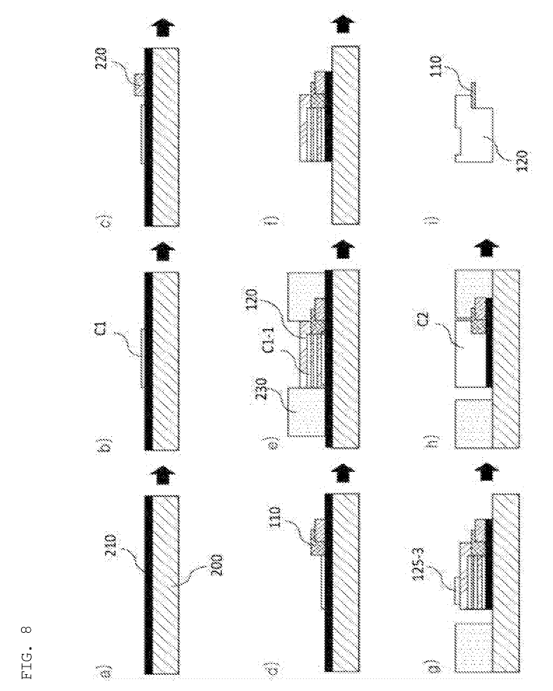

FIG. 8 is a view illustrating another example of a manufacturing process of a probe pin illustrated in FIG. 1.

As illustrated in FIG. 8, a manufacturing process of a probe pin 100 according to the present disclosure first involves forming a seed layer 210 on a wafer base 200 (e.g., Si, glass, ceramic) (a).

For example, the seed layer 210 in step (a) is formed by depositing thin films of titanium (Ti) and copper (Cu) on the wafer base 200 (e.g., Si, glass, ceramic). This seed layer 210 serves as the foundation for the plating process, providing a basis on which subsequent metal thin films can uniformly grow on the wafer 200.

Subsequently, the lowermost surface of the pin body portion 120 is laminated with a conductive layer C1 (e.g., gold (Au)) (b), and a copper base 220 serving as a support for a pin tip portion 110 of the probe pin 100 is formed (c).

Based on the laminated state of step (c), the pin tip portion 110 is formed with a high-hardness metal such as rhodium (Rh). This precision process may be implemented using a photolithography process (d).

After laminating the pin tip portion 110 in step (d), the portion forming the pin body portion 120 is formed with an Ni alloy. This contributes to maintaining the main structural shape of the probe pin 100. At this time, a conductive layer C1 (e.g., gold (Au)) may be additionally laminated alternately with the Ni alloy layer. Here, the conductive layer C1 may be formed not only with copper (Cu) or a copper (Cu) alloy but also with gold (Au) or a gold (Au) alloy. Without being limited thereto, it may be formed with other metals or other alloys that provide similar or equivalent effects. The additionally laminated conductive layer C1 (e.g., gold (Au)) may be provided either as a single structure on top of the aforementioned lowermost layer or as a multi-layer structure (e).

After step (e), a process of etching unnecessary portions of the seed layer 210 used in the previous step is carried out, leaving only a required selected area (f).

After step (f), a process of precisely selecting a specific area to be pattern-plated on the probe pin 100 using a photoresist 230 is carried out (g). A conductive layer C2 (e.g., gold (Au)) is then patterned-plated onto the precisely selected area (e.g., the area excluding the pin tip portion 110 and a solder wicking prevention area 125-3) defined in step (g) (h).

Thereafter, unnecessary portions including the residual seed layer 210 are etched to extract the probe pin (i).

While the present disclosure has been particularly shown and described with reference to exemplary embodiments thereof, those of ordinary skill in the art will appreciate that various changes in form and details may be made therein without departing from the spirit and scope of the present disclosure. The exemplary embodiments should be considered in descriptive sense only and not for purposes of limitation.

Additionally, the present disclosure provides a probe pin having a precisely defined selective conductive layer structure and a manufacturing method thereof, in which the probe pin is manufactured based on a conductive layer generation method employing precisely controlled selective lamination and pattern plating. This configuration enhances performance related to electrical characteristics, enhances performance capable of preventing contamination and damage of a pin tip portion, and reliably improves solder bonding strength with respect to a pad of a card substrate. The present disclosure not only has sufficient potential for commercialization and business application but is also practically and clearly implementable. Accordingly, the present disclosure possesses industrial applicability.

What is claimed is:

1. A probe pin having a precisely defined selective conductive layer structure, the probe pin comprising:
a pin body portion including a bonding portion bonded to a pad of a card substrate via solder, an elastic portion extending from the bonding portion, and a pin header portion extending from the elastic portion; and
a pin tip portion formed on a second side of the pin header portion,
wherein a lowermost surface of the pin body portion is formed as a conductive layer having a higher solder affinity than the pin tip portion.

2. The probe pin of claim 1, further comprising:
a pattern plating portion in which a conductive layer is pattern-plated only on a specific area free of the conductive layer on a surface of the pin body portion.

3. The probe pin of claim 1, wherein the bonding portion includes:
a soldering area in which the solder is applied and melted over at least one part of the pin body portion;
a solder wicking prevention area in which the conductive layer is not pattern-plated; and
a boundary area formed at a boundary between the soldering area and the solder wicking prevention area.

4. The probe pin of claim 1, wherein the conductive layer includes at least one selected from copper (Cu), gold (Au), silver (Ag), and alloys thereof.

5. The probe pin of claim 1, wherein the pin tip portion includes:
a pad contact area making contact with a pad to be inspected; and
a header connection area connected to the pin header portion,
wherein a part of the header connection area is pattern-plated with the conductive layer.

6. The probe pin of claim 3, wherein the solder wicking prevention area is surrounded by the conductive layer to form an enclosed structure.

7. The probe pin of claim 6, wherein a size of the solder wicking prevention area is determined based on a diffusion distance of the solder applied to the soldering area during bonding at the soldering area.

8. The probe pin of claim 1, wherein the conductive layer is further formed on an inner layer of the pin body portion either as a single structure or as a multi-layer structure.

9. The probe pin of claim 3, wherein laminated contact surfaces of the pin header portion and the header connection area include one or more interlocking engagement structures.

10. A manufacturing method of a probe pin including a pin body portion including a bonding portion bonded to a pad of a card substrate via solder, an elastic portion extending from the bonding portion, and a pin header portion extending from the elastic portion, and a pin tip portion formed on a second side of the pin header portion, the manufacturing method comprising:
forming a conductive layer having a higher solder affinity than the pin tip portion on a lowermost surface of the pin body portion.

11. The manufacturing method of claim 10, further comprising:
pattern-plating the conductive layer only on a specific area free of the conductive layer on a surface of the pin body portion.

12. The manufacturing method of claim 10, further comprising:
dividing the bonding portion into a soldering area in which the solder is applied and melted, a solder wicking prevention area in which the conductive layer is not pattern-plated, and a boundary area formed at a boundary between the soldering area and the solder wicking prevention area.

13. The manufacturing method of claim 10, further comprising:
dividing the pin tip portion into a pad contact area making contact with a pad to be inspected and a header connection area connected to the pin header portion, and pattern-plating a part of the header connection area with the conductive layer.

14. The manufacturing method of claim 11, further comprising:
precisely selecting the specific area to be pattern-plated through a photolithography process.

15. The manufacturing method of claim 14, wherein when the bonding portion is divided into a soldering area in which the solder is applied and melted, a solder wicking prevention area in which the conductive layer is not pattern-plated, and a boundary area formed at a boundary between the soldering area and the solder wicking prevention area, the solder wicking prevention area is excluded from pattern plating by the photolithography process.
